(19) United States
(12) Patent Application Publication
(10) Pub. No.: US 2022/0146086 A1
(43) Pub. Date: May 12, 2022

(54) LIGHT EMITTING AND RECEIVING MODULE WITH SNOW MELTING HEATER

(71) Applicant: NISSHA CO., LTD., Kyoto-shi, Kyoto (JP)

(72) Inventors: Takashi YOKOYAMA, Kyoto-shi, Kyoto (JP); Masateru CHIYAMA, Kyoto-shi, Kyoto (JP); Motoaki TOKUKURA, Kyoto-shi, Kyoto (JP); Yasuharu WATA, Kyoto-shi, Kyoto (JP); Hiroaki UEFUJI, Kyoto-shi, Kyoto (JP); Eiko SEKI, Kyoto-shi, Kyoto (JP)

(73) Assignee: NISSHA CO., LTD., Kyoto-shi, Kyoto (JP)

(21) Appl. No.: 17/602,837

(22) PCT Filed: Apr. 6, 2020
(86) PCT No.: PCT/JP2020/015516

§ 371 Date: Oct. 11, 2021

(30) Foreign Application Priority Data
Apr. 25, 2019 (JP) 2019-084372

(51) Int. Cl. F21V 29/90; H02S 40/12; H05B 3/03

(52) U.S. Cl. CPC F21V 29/90; H05B 2214/02; H05B 3/03; H02S 40/12

(57) ABSTRACT

A light emitting and receiving module with heater is provided, which includes a base material. A light emitting and receiving element is disposed on the base material and performs at least one of light reception and light emission. A heater film includes an electrode formed on a base sheet. The heater film is formed so as to cover the light emitting and receiving element. A capacitance detection unit electrically connected to the electrode detects a floating capacitance between the light emitting and receiving element and the heater film. A power source electrically connected to the electrode heats the heater film. A control board switches the connection with the electrode between the capacitance detection unit and the power source.

### CROSS REFERENCES TO RELATED APPLICATIONS

This application is a continuation of International Application No. PCT/JP2020/015516, filed on Apr. 6, 2020, which claims priority to Japanese Patent Application 2019-084372, filed on Apr. 25, 2019, which is incorporated herein by reference.

### TECHNICAL FIELD

The present disclosure relates to a light emitting and receiving module with snow melting heater.

### BACKGROUND

With a light receiving module provided with a light receiving element, such as a solar cell element, and a light emitting module provided with a light emitting element, such as an LED, when snow attaches to their surfaces during snowfall, sunlight and a light from the light emitting element are blocked, and therefore heaters for snow melting are provided on the surfaces of the modules in some cases. When snow attaches to the surface, the heater performs heating to melt the snow on the surface, ensuring efficiently receiving light or emitting light. For example, Patent Document 1 discloses a solar cell module with snow melting function in which a heater film made of a resin film on which electrodes are formed is stacked on the solar cell module.

### CITATION LIST

### Patent Literature

Patent Document 1: JP 2017-153196 A

### SUMMARY

### Problems to be Solved by the Present Disclosure

There may be a case where the conventional light emitting and receiving module with heater as described above includes detection means that detects snow adhesion to perform heating by the heater film only when snow attaches to the light emitting and receiving module. The snow adhesion is detected, for example, by detecting a change in electrostatic capacity due to snow adhesion using an electrostatic capacity sensor, and an electrode for electrostatic capacity sensor is formed on the heater film in addition to an electrode for heat generation. However, the electrode for capacitance sensor was formed on the heater film, and therefore an area where the electrode for heat generation was able to be formed was small and snow melting efficiency was deteriorated in some cases.

In order to solve the problem described above, an object of the present disclosure is to provide a light emitting and receiving module with snow melting heater provided with a heater film on which a single electrode having a function as a heating electrode for snow melting and also a function as an electrode of a capacitance detection sensor for detecting snow adhesion is formed.

### Features for Solving the Problems

To achieve the object described above, a first invention is a light emitting and receiving module with heater that includes a base material, a light emitting and receiving element, a heater film, a capacitance detection unit, a power source, and a control board. The light emitting and receiving element is disposed on the base material and performs at least one of light reception and light emission. In the heater film, an electrode is formed on a base sheet. The heater film is formed so as to cover the light emitting and receiving element. The capacitance detection unit is electrically connected to the electrode to detect a floating capacitance between the light emitting and receiving element and the heater film. The power source is electrically connected to the electrode to heat the heater film. The control board switches the connection with the electrode between the capacitance detection unit and the power source.

When configured in this manner, the heater film has a function as a heating electrode and also a function as an electrode of the capacitive detection sensor, and therefore snow melting can be performed only during snow adhesion without separately providing a snow adhesion detection sensor.

A second invention in the first invention is a light emitting and receiving module with heater in which the light emitting and receiving element is a solar cell element.

When configured in this manner, snow on the solar cell element can be melted during snowfall, so sunlight is not blocked and a light can be efficiently received.

A third invention is a light emitting and receiving module with heater in which the light emitting and receiving element is an LED.

When configured in this manner, snow on the LED can be melted during snowfall, so light emission by the LED is not blocked and the light can be recognized.

A fourth invention is a snow melting method of a light emitting and receiving module that detects snow adhesion when snow adheres to a light emitting and receiving module with heater that includes a light emitting and receiving element that performs at least one of light reception and light emission and a heater film in which an electrode is formed on a base sheet, and energizes the electrode to melt snow. The snow melting method includes: connecting the electrode to a capacitance detection unit to detect a floating capacitance between the light emitting and receiving element and the heater film; detecting presence or absence of the snow adhesion from the detected floating capacitance; switching the connection to the electrode from the capacitance detection unit to a power source when the snow adhesion is detected to switch a capacitance detection state to a heater energization state; heating the electrode to melt snow; and switching the connection to the electrode from the power source to the capacitance detection unit after an elapse of any given period to switch the heater energization state to the capacitance detection state.

When configured in this manner, the heater can be in the energization state only during the snow adhesion, thus ensuring efficiently melting the snow.

A fifth invention in the fourth invention is a snow melting method that, when at least one of an atmospheric temperature and a temperature of the heater film is 0° C. or less, the detecting detects presence of the snow adhesion when the floating capacitance between the light emitting and receiving element and the heater film changes.

When configured in this manner, since whether the change in floating capacitance is caused by water or snow can be determined from the temperature of outside air or the temperature of the film heater, in the case where the floating capacitance changes due to rain, the heater does not operate, and when the floating capacitance changes due to snow adhesion, the heater operates.

A sixth invention in the fourth invention is a snow melting method in which, when the floating capacitance between the light emitting and receiving element and the heater film is from 100 pF to 50 nF, the detecting detects that the snow adhesion is present.

When configured in this manner, only the snow adhesion can be detected from the value of the floating capacitance, and therefore, the heater can be operated only during the snow adhesion and the snow can be efficiently melted.

### Advantageous Effects of Disclosure

According to the present disclosure, the light emitting and receiving module with heater provided with the heater film formed with the single electrode having a snow adhesion detection function and also a snow melting function can be obtained.

### BRIEF DESCRIPTION OF DRAWINGS

FIG. 1 includes cross-sectional views illustrating schematic configurations of light emitting and receiving modules with heaters according to a first embodiment to a third embodiment of the present disclosure.

FIG. 2 is a block diagram illustrating a configuration of the light emitting and receiving module with heater according to the first embodiment of the present disclosure.

FIG. 3 is a flowchart depicting operations of the light emitting and receiving module with heater according to the first embodiment of the present disclosure.

FIG. 4(a) is a front view of a light emitting and receiving module with heater according to a fourth embodiment of the present disclosure, FIG. 4(b) is a schematic cross-sectional view of the light emitting and receiving module with heater taken along the line I-I, and FIG. 4(c) is a schematic cross-sectional view of the light emitting and receiving module with heater taken along the line II-II.

FIG. 5 is a block diagram illustrating a configuration of the light emitting and receiving module with heater according to the fourth embodiment of the present disclosure.

### DETAILED DESCRIPTION

Embodiments of the invention will be described with reference to the drawings.

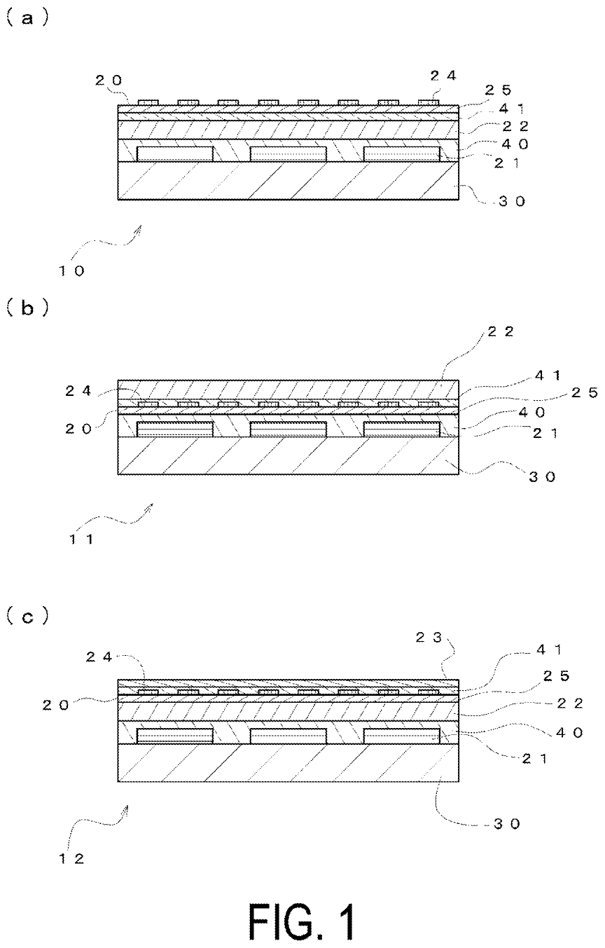

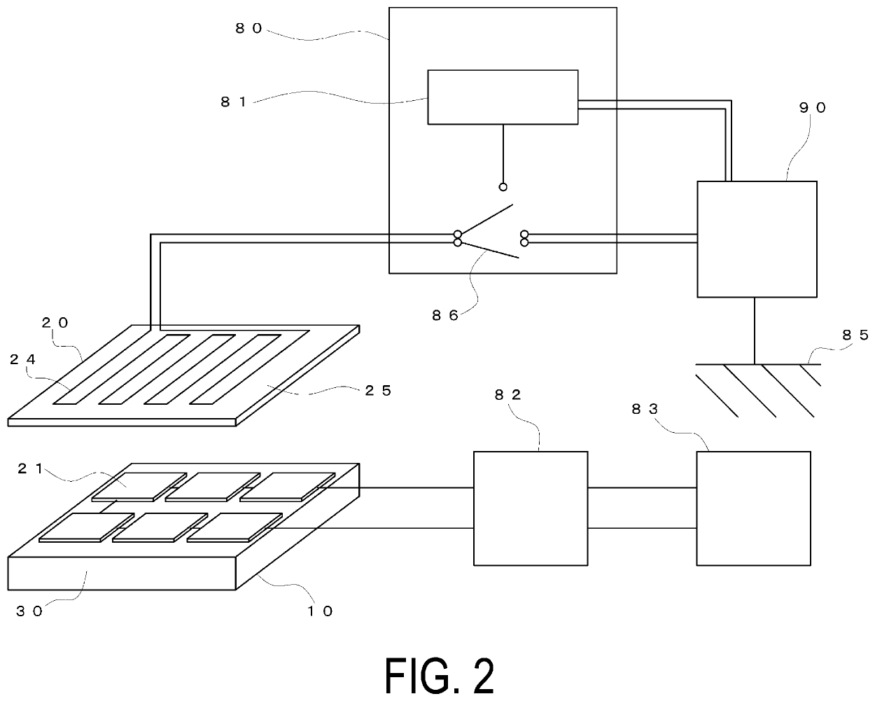

With reference to FIG. 1(a) and FIG. 2, a light emitting and receiving module with heater according to a first embodiment of the present disclosure is a solar cell module with heater 10 that includes a plate-like base material 30, six solar cell elements 21 connected in series on the base material 30, a first adhesive layer 40 formed on the base material 30 so as to cover the solar cell elements 21, a glass 22 formed on the first adhesive layer 40, a second adhesive layer 41 formed on the glass 22, and a heater film 20 formed on the second adhesive layer 41. The solar cell elements 21 are connected to an inverter 82 through an external circuit. Further, the inverter 82 is connected to a power meter 83 and connected to an iron tower via a power transmission line (not illustrated) from the power meter 83. The heater film 20 includes an electrode 24 formed by disposing one wiring line in a serpentine pattern on a base sheet 25. The electrode 24 has both ends connected to a control board 80 via an external circuit, and the control board 80 is connected to a power source 90 grounded to a grounding portion 85.

The base material 30 is to support the solar cell elements 21. For example, a glass or a resin film can be used as the material. For example, as the resin film, polyethylene terephthalate, polyester, or polyimide can be used.

For example, as the solar cell elements 21, silicon solar cells, compound solar cells, organic solar cells, and organic-inorganic hybrid solar cells can be used. As the silicon solar cells, for example, monocrystalline silicon, polycrystalline silicon, and amorphous silicon can be used as the material of the solar cells. As the compound solar cells, for example, CIS solar cells or CdTe solar cells can be used. As the organic solar cells, for example, organic thin-film solar cells and dye-sensitized solar cells can be used. As the organic-inorganic hybrid solar cells, for example, perovskite solar cells can be used. While the six solar cell elements 21 are formed in series, any number of one or two or more solar cell elements 21 may be used. Furthermore, in the case of using the two or more solar cell elements 21, each of the solar cell elements 21 may be connected in series or may be connected in parallel.

A resin film can be used as the base sheet 25 used in the heater film 20. For example, polyethylene terephthalate, polycarbonate, polyimide, polyamide, polyurethane, PMMA, polyethylene, polypropylene, and polyethylene naphthalate can be used. The thickness of the base sheet 25 can be, for example, from 50 μm to 500 μm. The thickness of the base sheet of 50 μm or more allows obtaining sufficient durability, the thickness of 500 μm or less allows suppressing excessively high haze, and thus sunlight can efficiently pass through the solar cell elements 21. The electrode 24 functions as a capacitive detection electrode to detect accumulated snow on a surface of the solar cell module 10 and also functions as a heating electrode to melt the accumulated snow. The capacitance detection function and the snow melting function of the electrode 24 can be switched by the control board 80. As the material of the electrode 24, for example, gold, silver, copper, iron, aluminum, nickel, and molybdenum, and alloys containing them can be used. The electrode 24 can have a line width of, for example, from 1 μm to 60 μm. When the line width is 1 μm or more, disconnection is less likely to occur at the line width, and when the line width is 60 μm or less, since reflection and absorption of sunlight by the electrode 24 can be suppressed, the sunlight easily reaches the solar cell elements 21. The thickness of the electrode 24 can be, for example, from 100 nm to 15 μm, when the thickness is 100 nm or more, disconnection is less likely to occur at the thickness, and when the thickness is 15 μm or less, a resistance value of the electrode 24 does not become excessively low, a pitch of the electrode 24 can be narrowed, and a heat generation area can be increased. As a result, heating can be performed efficiently. Furthermore, the shape of the electrode 24 is not limited to the serpentine shape of the single wiring line, and may be, for example, a mesh shape. By configuring the shape of the electrode 24 in the mesh shape, a defect caused by disconnection can be suppressed.

The glass 22 is used as a base material to protect the solar cell elements 21 and to support the heater film 20 above the solar cell elements 21. The glass 22 only need to be transparent to the extent of not blocking sunlight, and, for example, an inorganic glass or a resin glass can be used.

The first adhesive layer 40 and the second adhesive layer 42 are used to stack the respective components. The first adhesive layer 40 and the second adhesive layer 42 only need to be transparent to the extent of not blocking sunlight, and, for example, a hot melt adhesive or a curable adhesive can be used.

With reference to FIG. 2, the control board 80 includes a capacitance detection unit 81 that detects a change in floating capacitance between the heater film 20 and the solar cell elements 21, and a switch 86 that switches between the capacitance detection function and the snow melting function of the electrode 24. The switch 86 is connected to the electrode 24, the capacitance detection unit 81, and the power source 90, and switching the switch 86 by the control board 80 makes it possible to switch the connection with the electrode 24 between the capacitance detection unit 81 and the power source 90. In addition to the connection with the switch 86, the capacitance detection unit 81 is connected to the power source 90. When the capacitance detection unit 81 is connected to the electrode 24 with the switch 86, power is supplied from the power source 90 to ensure measuring the floating capacitance between the heater film 20 and the solar cell elements 21. On the other hand, when the electrode 24 and the power source 90 are directly connected with the switch 86, power is supplied from the power source 90 to the electrode 24 and the heater film 20 generates heat, thereby allowing melting snow.

Next, the capacitance detection function of the electrode 24 will be described.

When the electrode 24 is connected to the capacitance detection unit 81 with the switch 86, the floating capacitance between the heater film 20 and the solar cell elements 21 can be measured. When a case in which snow does not adhere to the surface of the solar cell module with heater 10 is set as the initial value of the floating capacitance, in a case where snow adheres to the surface of the solar cell module with heater 10, the floating capacitance increases. Therefore, detecting the change in floating capacitance allows detection of presence or absence of snow adhesion. However, since the floating capacitance also increases when water droplets attach to the surface of the solar cell module with heater due to rain and melted snow, the attachment of water droplets is possibly detected that snow adheres even when snow does not adhere.

Accordingly, a temperature may be further set as a threshold, and snow adhesion may be detected. For example, when at least one of an atmospheric temperature and a temperature of the heater film 20 is any given temperature or less, it may be detected that snow adhesion occurs only when the floating capacitance between the heater film 20 and the solar cell elements 21 changes. When configured in this manner, in a case where the floating capacitance changes at the temperature of any given temperature or less, it is detected that the floating capacitance changes due to snow adhesion, and snow can be melted by the heater film 20. On the other hand, in a case where the floating capacitance changes at the temperature higher than any given temperature, it is detected that the floating capacitance changes due to water droplets of rainfall or the like to ensure avoiding heating by the heater film 20. The threshold of the temperature can be, for example, 0° C. or less, and when the floating capacitance changes at 0° C. or less, it can be detected that snow adheres.

Additionally, as another method of detection only when snow actually adheres, an amount of increase in floating capacitance from the initial value may be set as a threshold. The amount of increase in floating capacitance due to water droplets is larger than the amount increase in floating capacitance due to snow adhesion. Thus, for example, when the floating capacitance increases from the initial value by 20% to 50%, it can be detected that snow adheres. When the change in floating capacitance is within this range, it is detected that snow adheres, and the heater film 20 can perform snow melting.

Further, as another method of detecting only the case of actual snow adhesion, the change in floating capacitance for a certain period may be set as a threshold. During snowfall, snow adheres to the surface of the solar cell module with heater 10, and the floating capacitance increases from the initial value and after that becomes a constant value. On the other hand, during rainfall, since water droplets adhere to the surface of the solar cell module with heater 10, the floating capacitance increases from the initial value. However, the water droplets flow down outside from the surface of the solar cell module 10 and new water droplets attach, so the floating capacitance fluctuates without taking a constant value. Thus, by setting the change in floating capacitance for a certain period as the threshold, only snow adhesion can be detected. As the threshold, for example, the threshold can be set to detect snow adhesion only when the change in floating capacitance in one hour is 20% or less.

Only one of the respective method for using the temperature as the threshold, method for using the increase in amount of floating capacitance from the initial value as the threshold, and method for using the change in floating capacitance for a certain period as the threshold, which are the methods to detect only snow adhesion, may be used or a plurality of them may be used in combination. The combination use of the plurality of methods allows more accurate snow adhesion detection. For example, in the method that uses the change in floating capacitance for a certain period as the threshold, when an amount of rainfall is small, since the change in floating capacitance for a certain period is small, there may be a case where detection whether the change in floating capacitance is caused by snow adhesion or water droplets due to rainfall is difficult. In this case, by further using the temperature as the threshold and combining the two methods, even when the change in floating capacitance for a certain period is small, when the temperature is any given temperature or less, it is detected as snow adhesion, and when the temperature is higher than any given temperature, it can be detected as attachment of water droplets due to rainfall.

Next, the snow melting function of the electrode 24 will be described.

In a case where snow adhesion is detected in the solar cell module with heater 10 by a snow adhesion detection function of the electrode 24, the connection with the electrode 24 is switched to the connection with the power source 90 by the switch 86, power is supplied from the power source 90 to the electrode 24, and the electrode 24 generates heat. The heat generation of the electrode 24 heats the surface of the solar cell module with heater 10, and thus the snow attached to the surface can be melted. After that, after the heating is performed for a certain period, the switch 86 is switched, and the connection with the electrode 24 is connected to the capacitance detection unit 81. As the heating period, any period, for example, 10 minutes can be set. When the electrode 24 is connected to the power source 90 with the switch 86 and the heater performs heating for 10 minutes, the switch 86 is automatically switched, the electrode 24 is connected to the capacitance detection unit 81, and the detection of presence or absence of snow adhesion is performed again. Switching with the switch 86 may be configured to be automatically switched after the heating is performed for a certain period or to manually switch the switch 86.

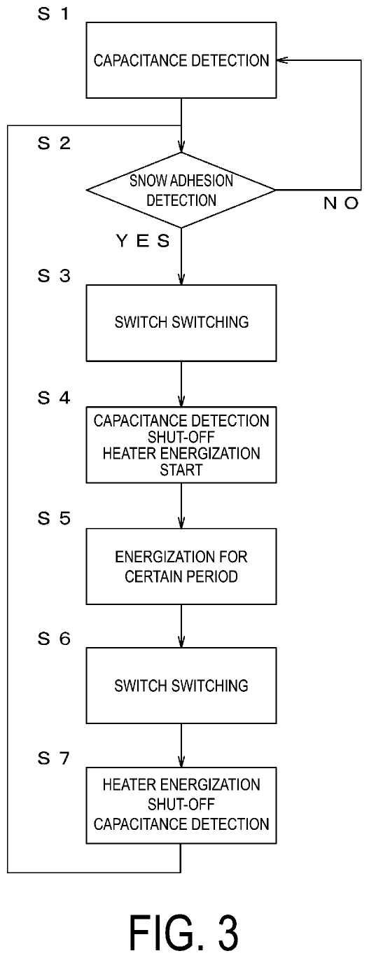

Next, a series of operations of the solar cell module with heater 10 according to the first embodiment of the present disclosure will be described with reference to FIG. 3. As a capacitance detecting step, the electrode 24 of the heater film 20 is connected to the capacitance detection unit 81 via the switch 86, and the capacitance detection unit 81 detects the floating capacitance between the heater film 20 and the solar cell elements 21. Next, in a case where there is no change in the detected floating capacitance value, the control board 80 detects that there is no snow adhesion and does not switch the switch 86. On the other hand, when the detected floating capacitance increases from the initial value, it is detected that snow adhesion is present, and the process moves to a first switch switching step. Next, in the first switch switching step, the switch 86 is operated by the control board 80 to switch the connection with the electrode 24 from the capacitance detection unit 81 to the power source 90. Thus, capacitance detection is shut off, and the capacitance detection state switches to a heater energization state. Next, power is supplied from the power source 90 to the electrode 24 and the heater film 20 is heated to melt the snow attached to the surface of the solar cell module with heater 10. Next, after the heater film 20 performs the heating for 10 minutes, the step moves to a second switch switching step. Next, in the second switch switching step, the switch 86 is operated by the control board 80 and the connection with the electrode 24 is switched from the power source 90 to the capacitance detection unit 81, and thus the heater energization state switches to the capacitance detection state. Thereafter, when the floating capacitance between the heater film 20 and the solar cell elements 21 is detected and the floating capacitance increases from the initial value, the heater film 20 performs heating again. Through such a series of operations, the snow attached to the surface of the solar cell module with heater 10 is detected and melted.

With the solar cell module with heater 10 as described above, the single electrode 24 formed on the heater film 20 can perform both of snow adhesion detection and snow melting by switching the switch 86, so it is not necessary to separately provide an electrode for snow adhesion detection sensor and snow melting can be performed only during snow adhesion.

Next, the following will describe a second embodiment of the present disclosure mainly in points different from the above-described embodiment with reference to the drawings.

With reference to FIG. 1(b), a light emitting and receiving module with heater according to the second embodiment of the present disclosure is a solar cell module with heater 11. The solar cell module with heater 11 differs from the solar cell module with heater according to the above-described embodiment in stacked configuration. On the other hand, each component constituting the solar cell module with heater 11 and the snow melting method are the same as those in the above-described embodiment.

The solar cell module with heater 11 includes the plate-like base material 30, the solar cell elements 21 formed on the base material 30, the first adhesive layer 40 formed so as to cover the solar cell elements 21, the heater film 20 formed on the first adhesive layer 40, the second adhesive layer 41 formed so as to cover the heater film 20, and the glass 22 formed on the second adhesive layer 41. In the solar cell module with heater 10 according to the first embodiment, the glass 22 is disposed below the heater film 20, and the heater film is exposed to the surface, but the solar cell module with heater 11 according to the second embodiment includes the glass 22 disposed above the heater film 20. By disposing the glass 22 above the heater film 20, the heater film 20 can be protected by the glass 22, and damage to the electrode 24 and the base sheet 25 of the heater film 20 can be suppressed.

Other materials and a series of operations performing the snow adhesion detection and the snow melting are the same as those in the above-described embodiment.

Next, the following will describe a third embodiment of the present disclosure mainly in points different from the above-described embodiments with reference to the drawing.

With reference to FIG. 1(c), a light emitting and receiving module with heater according to the third embodiment of the present disclosure is a solar cell module with heater 12. The solar cell module with heater 12 differs from the solar cell modules with heaters according to previous embodiments in stacked configuration, and a protective layer 23 is formed on the surface. On the other hand, the other components constituting the solar cell module with heater 12 and the snow melting method are the same as those in the above-described embodiments.

The solar cell module with heater 12 includes the plate-like base material 30, the solar cell elements 21 formed on the base material 30, the first adhesive layer 40 formed so as to cover the solar cell elements 21, the glass 22 formed on the first adhesive layer 40, the heater film 20 formed on the glass 22, the second adhesive layer 41 formed so as to cover the heater film 20, and the protective layer 23 formed on the second adhesive layer 41.

The protective layer 23 is to protect the surface of the heater film 20. The protective layer 23 can be formed by coating a resin, and, for example, acrylic, fluororesin, silicone, and urethane can be used. Since the resin used as the protective layer 23 has a thin thickness, the protective layer 23 easily transmits heat compared with the glass. Therefore, the heat from the heater film 20 can be efficiently transmitted to a surface of a solar cell module with heater 13, thus ensuring efficiently melting the snow. The thickness of the protective layer 23 is preferably, for example, from 100 nm to 15 μm. The thickness of 100 nm or more allows the heater film 20 to be less likely to be damaged by external force, and the thickness of 15 μm or less allows efficiently transmitting the heat from the heater film 20 to the surface of the solar cell module with heater 13.

Other materials and a series of operations performing the snow adhesion detection and the snow melting are the same as those in the above-described embodiments.

Next, the following will describe a fourth embodiment of the present disclosure with reference to the drawings.

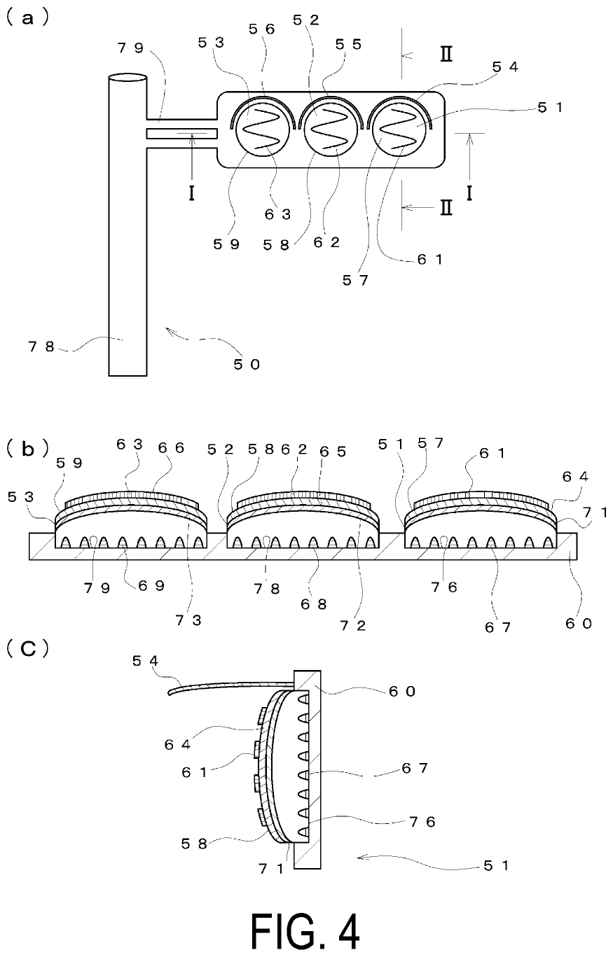

With reference to FIG. 4(a), a light emitting and receiving module with heater according to the fourth embodiment of the present disclosure is a traffic light with heater 50. In the traffic light with heater 50, two columnar cross arms 79 thinner than a columnar signal post 78, which is installed on the ground, are connected so as to extend from the signal post 78 in the horizontal direction. A box-shaped base material 60 extending in the horizontal direction is connected to end portions on the side opposite to the signal post 78 of the cross arms 79. A lighting apparatus 51, a lighting apparatus 52, and a lighting apparatus 53 that indicate whether pedestrians and vehicles are permitted to travel are formed on the base member 60. A hood 54, a hood 55, and a hood 56 are formed above the lighting apparatus 51, the lighting apparatus 52, and the lighting apparatus 53, respectively, in the direction perpendicular to the ground so as to cover upper portions of the lighting apparatus 51, the lighting apparatus 52, and the lighting apparatus 53.

Next, a cross-sectional structure of the lighting apparatus 51 will be described with reference to FIG. 4(b) and FIG. 4(c). A region where the lighting apparatus 51 is formed is a recessed portion 74 in the base member 60, and a plurality of LEDs 67 are formed in the recessed portion 74 of the base member 60. Additionally, a lens 71 with a surface having a curved convex shape is formed so as to cover the recessed portion 74 of the base material 60. Further, a heater film 57 that covers the lens 71 is formed on the lens 71 along the curved surface of the lens 71. Similarly to the lighting apparatus 51, a recessed portion 75 and a recessed portion 76 of the lighting apparatus 52 and the lighting apparatus 53, respectively, are formed in the base material 60, and LEDs 67 and LEDs 68 are formed on the recessed portion 75 and the recessed portion 76. Further, a lens 72 and a lens 73 are formed so as to cover the recessed portion 75 and the recessed portion 76 of the base material 60, and a heater film 58 and a heater film 59 are formed on the lens 72 and lens 73. In the heater film 57, the heater film 58, and the heater film 59, an electrode 61, an electrode 62, and an electrode 63 formed by disposing one wiring line in a serpentine pattern are formed on the base sheet 64, a base sheet 65, and a base sheet 66, respectively.

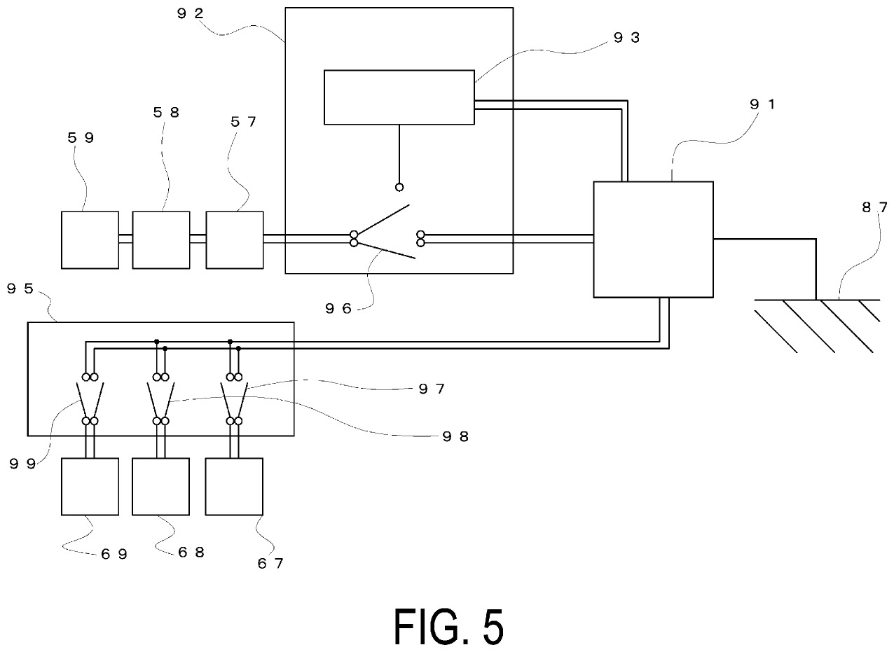

With reference to FIG. 5, the heater film 57, the heater film 58, and the heater film 59 are connected with an external circuit, and the heater film 57 is further connected to a heater film control board 92. The heater film control board 92 is connected to a power source 91 grounded to a grounding portion 87. On the other hand, the LEDs 67, the LEDs 68, and the LEDs 69 are each independently connected to an LED lighting control board 95. The three wiring lines extending from the LEDs 67, the LEDs 68, and the LEDs 69 are connected to the one at the outside of the LED lighting control board 95 and connected to the power source 91 installed to the grounding portion 87.

The heater film control board 92 includes a capacitance detection unit 93 and a heater film switch 96. The capacitance detection unit 93 detects a change in floating capacitance formed between the heater film 57 and the LEDs 67, the heater film 58 and the LEDs 68, and the heater film 59 and the LEDs 69. The heater film switch 96 performs switching between the capacitance detection function and the snow melting function of the electrode 61, the electrode 62, and the electrode 63. The heater film switch 96 is connected to the electrode 61, the capacitance detection unit 93, and the power source 91. Switching the heater film switch 96 by the heater film control board 92 allows switching the connection with the electrode 61 between the capacitance detection unit 93 and the power source 91. In addition to the connection with the heater film switch 96, the capacitance detection unit 93 is connected to the power source 91. When the capacitance detection unit 93 is connected to the electrode 61 with the heater film switch 96, power is supplied from the power source 90 to the electrode 61, the electrode 62, and the electrode 63, and thus the floating capacitance between the heater film 57 and the LEDs 67, the heater film 58 and the LEDs 68, and the heater film 59 and the LEDs 69 can be measured. On the other hand, when the electrode 61 and the power source 91 are directly connected with the heater film switch 96, power is supplied from the power source 90 to the electrode 61, the electrode 62, and the electrode 63, and thus the heater film 57, the heater film 58, and the heater film 59 generate heat and the snow can be melted.

The LED lighting control board 95 includes an LED lighting switch 97, an LED lighting switch 98, and an LED lighting switch 99 that switch lighting of the LEDs 67, the LEDs 68, and the LEDs 69 between on and off. The wiring line out of the LEDs 67 is connected to the LED lighting switch 97, the wiring line out of the LEDs 68 is connected to the LED lighting switch 98, and the wiring line out of the LEDs 69 is connected to the LED lighting switch 99. The three wiring lines out of the LED lighting switch 97, the LED lighting switch 98, and the LED lighting switch 99 are bundled to a single wiring line and connected to the power source 91. The LED lighting control board 95 controls the switching of the LED lighting switch 97, the LED lighting switch 98, and the LED lighting switch 99. In general, the LED lighting switch 97, the LED lighting switch 98, and the LED lighting switch 99 are switched so that any of the LEDs 67, the LEDs 68, and the LEDs 69 lights or flashes.

The base material 60 is a housing of lighting portions of the traffic light with heater 50. As an example of the material, a metal and a resin can be used. As an example of the metal, aluminum and iron can be used, and as an example of the resin, polycarbonate and fiber-reinforced resin (FRP) can be used.

The hood 54, the hood 55, and the hood 56 are to reduce dirtying the lighting apparatus 51, the lighting apparatus 52, and the lighting apparatus 53 and ensure visibility by blocking sunlight. The same material as the base material 60 can be used as the material.

A resin film can be used as the base sheet 64, the base sheet 65, and the base sheet 66 used for the heater film 57, the heater film 58, and the heater film 59. For example, polyethylene terephthalate, polycarbonate, polyimide, polyamide, polyurethane, PMMA, polyethylene, polypropylene, and polyethylene naphthalate can be used. The thickness of the base sheet can be, for example, from 50 μm to 500 μm. The thickness of the base sheet of 50 μm or more allows obtaining sufficient durability, the thickness of 500 μm or less allows suppressing excessively high haze, and thus light emitted by the LEDs can efficiently pass through the base sheet. The electrode 61, the electrode 62, and the electrode 63 function as capacitive detection electrodes to detect accumulated snow on surfaces of the lighting apparatus 51, the lighting apparatus 52, and the lighting apparatus 53 and also function as heating electrodes to melt the accumulated snow. The capacitance detection function and the snow melting function of the electrodes can be switched by the heater film control board 92. As the material of the electrodes, for example, gold, silver, copper, iron, aluminum, nickel, and molybdenum, and alloys containing one or more kinds of them can be used. The electrode can have a line width of, for example, from 1 μm to 60 μm. When the line width is 1 μm or more, disconnection is less likely to occur at the line width, and when the line width is 60 μm or less, since reflection and absorption of light from the LEDs by the electrodes can be suppressed, a pedestrian and a driver of a vehicle can recognize the light from the LEDs. The thickness of the electrode 24 can be, for example, from 100 nm to 15 μm, when the thickness is 100 nm or more, disconnection is less likely to occur at the thickness, and when the thickness is 15 μm or less, a resistance value of the electrode 24 does not become excessively low, a pitch of the electrode 24 can be narrowed, and a heat generation area can be increased. As a result, heating can be performed efficiently. Furthermore, the shape of the electrode is not limited to the serpentine shape of the single wiring line, and may be, for example, a mesh shape. By configuring the shape of the electrode in the mesh shape, a defect caused by disconnection can be suppressed.

To determine whether the pedestrian and the driver of the vehicle are permitted to travel, the respective LEDs 67, LEDs 68, and LEDs 69 emit lights in different colors. For example, the LEDs 67, the LEDs 68, and the LEDs 69 emit lights in red, yellow, and blue, respectively. The pedestrian and the driver of the vehicle stop without travelling when they recognize the emission of light in red. When they recognize the emission of light in yellow, they stop without travelling in principle, but in a case where they cannot stop safely up to a set stop position, they travel. When they recognize the emission of light in blue, they are permitted to travel. In this way, the pedestrian and the driver of the vehicle can determine whether the travelling is permitted from the color of the light emitted by the LEDs.

Next, the capacitance detection function of the electrode 61, the electrode 62, and the electrode 63 will be described.

When the electrode 61, the output electrode 62, and the electrode 63 are connected to the capacitance detection unit 93 with the heater film switch 96, the floating capacitance between the LEDs 67 and the electrode 61, between the LEDs 68 and the electrode 62, and between the LEDs 69 and the electrode 63 can be measured. When a case in which snow does not adhere to the surface of the lighting apparatus 51, the lighting apparatus 52, or the lighting apparatus 53 of the traffic light with heater 50 is set as the initial value of the floating capacitance, in a case where snow adheres to the surface of the lighting apparatus 51, the floating capacitance between the LEDs 67 and the electrode 61 increases. Similarly, in a case where snow adheres to the surface of the lighting apparatus 52, the floating capacitance between the LEDs 68 and the electrode 62 increases, and in a case where snow adheres to the surface of the lighting apparatus 53, the floating capacitance between the LEDs 69 and the electrode 64 increases. When any of these floating capacitances increases, the capacitance detection unit 93 detects the increase in floating capacitance and can detect the presence or absence of snow adhesion.

Note that the heater film 57, the heater film 58, and the heater film 59 are configured to be connected to one heater control board 92, but the heater film 57, the heater film 58, and the heater film 59 may be each connected independently to three heater control boards. With such a configuration, the presence or absence of snow adhesion to the surfaces of the lighting apparatus 51, the lighting apparatus 52, and the lighting apparatus 53 can be detected individually, and snow melting can be performed on only the lighting apparatus where snow adhesion is detected. Alternatively, in a case where any of the heater film control boards undergoes a malfunction, and it is detected that there is no snow adhesion by the malfunction although snow adheres to any of the lighting apparatuses, by providing a plurality of heater film control boards, when the heater film control board detects snow adhesion in another lighting apparatus, setting can be configured such that snow melting is performed on all of the lighting apparatuses.

Furthermore, all of the heater film 57, the heater film 58, and the heater film 59 need not be connected to the heater film control board 92, and any one or two heater films may be connected to the heater film control board 92. With this configuration, the heater film not connected to the heater film control board 92 only need to have the snow melting function by heat generation, and the configuration is more simplified.

For ease of detection of only snow adhesion without detection of water droplets, the method for using the temperature as the threshold, the method for using the increase in amount of floating capacitance from the initial value as the threshold, and the method for using the change in floating capacitance for a certain period as the threshold, which have been described in the light emitting and receiving module with heater according to the first embodiment, may be used.

Next, the snow melting function of the electrode 61, the electrode 62, and the electrode 63 will be described.

In a case where snow adhesion is detected in the traffic light with heater 50 by the snow adhesion detection function of the electrode 61, the electrode 62, and the electrode 63, the connection with the electrodes is switched to the connection with the power source 91 by the heater film switch 96, power is supplied from the power source 91, and the electrodes generate heat. The heat generation of the electrodes heat the surfaces of the lighting apparatuses of the traffic light with heater 50, and thus the snow attached to the surfaces can be melted. After that, after the heating is performed for a certain period, the switch 86 is switched, and the connection with the electrodes is connected to the capacitance detection unit 93. As the heating period, any period, for example, 10 minutes can be set. When the electrodes are connected to the power source 91 with the heater film switch 96 and the heater performs heating for 10 minutes, the heater film switch 96 is automatically switched, the electrodes are connected to the capacitance detection unit 93, and the detection of presence or absence of snow adhesion is performed again. Switching with the heater film switch 96 may be configured to be automatically switched after the heating is performed for a certain period or to manually switch the heater film switch 96.

Next, a series of operations of the traffic light with heater 50 according to the fourth embodiment of the present disclosure will be described. As the capacitance detecting step, the electrode of the heater film is connected to the capacitance detection unit 93 via the heater film switch 96, and the capacitance detection unit 93 detects the floating capacitance between the heater film and the LEDs. Next, in a case where there is no change in the detected floating capacitance value, the control board 93 detects that there is no snow adhesion and does not switch the heater film switch 96. On the other hand, when the detected floating capacitance increases from the initial value, it is detected that snow adhesion is present, and the process moves to the first switch switching step. Next, in the first switch switching step, the heater film switch 96 is operated by the heater film control board 92 to switch the connection with the electrodes from the capacitance detection unit 93 to the power source 91. Thus, capacitance detection is shut off, and the capacitance detection state switches to the heater energization state. Next, power is supplied from the power source 91 to the electrodes and the heater films are heated to melt the snow attached to the surfaces of the lighting apparatuses of the traffic light with heater 50. Next, after the heater films perform the heating for 10 minutes, the step moves to the second switch switching step. Next, in the second switch switching step, the heater film switch 96 is operated by the heater film control board 92 and the connection with the electrodes is switched from the power source 91 to the capacitance detection unit 93, and thus the heater energization state switches to the capacitance detection state. Thereafter, when the floating capacitance between the heater film and the LEDs is detected and the floating capacitance increases from the initial value, the heater film performs heating again. Through such a series of operations, the snow attached to the surface of the traffic light with heater 50 is detected and melted. During the snow adhesion detection and the snow melting using the heater films by the series of operations, the lighting apparatuses are independently lit on or off, and the LED lighting control board 95 switches the LED lighting switch 96, the LED lighting switch 97, and the LED lighting switch 98.

With the traffic light with heater 50 as described above, the single electrode formed on the heater film can perform both of snow adhesion and snow melting by switching the heater film switch 96, so it is not necessary to separately provide an electrode for snow adhesion detection sensor and snow melting can be performed only during snow adhesion.

While the light emitting and receiving module with heater according to each of the embodiments described above uses the solar cell element as the light receiving element and the LEDs used for the traffic light as the light emitting elements, but the light receiving element and the light emitting element are not limited thereto, and any given ones can be used. For example, an incandescent light, a fluorescent light, a fluorescent tube, an organic EL, a laser diode, a photodiode, a CCD, a photoresistor, a photomultiplier tube, a CMOS sensor, a pyroelectric element, and a bolometer can be used.

In the light emitting and receiving modules with heaters according to the first embodiment and the fourth embodiment of the present disclosure, the heater film in which the electrode is formed on the base sheet is formed so as to cover the light emitting and receiving elements with the surface on which the electrode is not formed on the light emitting and receiving element side. However, the heater film may be formed so as to cover the light emitting and receiving elements while the surface on which the electrode is formed of the heater film is oriented to the light emitting and receiving element side.

### BRIEF DESCRIPTION OF THE REFERENCE NUMERALS

10 Solar cell module with heater
11 Solar cell module with heater
12 Solar cell module with heater
20 Heater film
21 Solar cell element
24 Electrode
25 Base sheet
50 Traffic light with heater
57 Heater film
58 Heater film
59 Heater film
60 Base material
61 Electrode
62 Electrode
63 Electrode
64 Base sheet
65 Base sheet
66 Base sheet
67 LED
68 LED
69 LED
80 Control board
81 Capacitance detection unit
90 Power source
91 Power source
92 Heater film control board
93 Capacitance detection unit

1. A light emitting and receiving module with a heater comprising:
a base material;
a light emitting and receiving element that is disposed on the base material and performs at least one of light reception and light emission;
a heater film in which an electrode is formed on a base sheet, the heater film being formed so as to cover the light emitting and receiving element;
a capacitance detection unit electrically connected to the electrode to detect a floating capacitance between the light emitting and receiving element and the heater film;
a power source electrically connected to the electrode to heat the heater film; and
a control board that switches the connection with the electrode between the capacitance detection unit and the power source.

2. The light emitting and receiving module with a heater according to claim 1, wherein
the light emitting and receiving element is a solar cell element.

3. The light emitting and receiving module with a heater according to claim 1, wherein
the light emitting and receiving element is a light-emitting diode (LED.

4. A snow melting method of a light emitting and receiving module that detects snow adhesion when snow adheres to a light emitting and receiving module with a heater that includes a light emitting and receiving element that performs at least one of light reception and light emission and a heater film in which an electrode is formed on a base sheet, wherein the light emitting and receiving element energizes the electrode to melt snow, the snow melting method comprising:
connecting the electrode to a capacitance detection unit to detect a floating capacitance between the light emitting and receiving element and the heater film;
detecting presence or absence of the snow adhesion from the detected floating capacitance;
switching the connection to the electrode from the capacitance detection unit to a power source when the snow adhesion is detected to switch a capacitance detection state to a heater energization state;
heating the electrode to melt the snow; and
switching the connection to the electrode from the power source to the capacitance detection unit after an elapse of a given period to switch the heater energization state to the capacitance detection state.

5. The snow melting method according to claim 4, wherein
when at least one of an atmospheric temperature and a temperature of the heater film is 0° C. or less, the detecting detects presence of the snow adhesion when the floating capacitance between the light emitting and receiving element and the heater film changes.

6. The snow melting method according to claim 4, wherein
when the floating capacitance between the light emitting and receiving element and the heater film is from 100 pF to 50 nF, the detecting detects that the snow adhesion is present.

7. The light emitting and receiving module with a heater according to claim 1, further comprising a glass layer disposed between the light emitting and receiving element and the heater film.

8. The light emitting and receiving module with a heater according to claim 1, further comprising a glass layer disposed above the heater film.

9. The light emitting and receiving module with a heater according to claim 1, further comprising a protective layer formed on a surface of the heater film.

10. The light emitting and receiving module with a heater according to claim 9, wherein the protective layer includes a thickness from 100 nm to 15 μm.

11. The light emitting and receiving module with a heater according to claim 1, further comprising an adhesive layer formed to cover at the light emitting and receiving element.

12. The light emitting and receiving module with a heater according to claim 1, further comprising an adhesive layer formed to cover the electrode of the heater film.

13. The light emitting and receiving module with a heater according to claim 1, wherein the electrode includes a line width of 1 μm to 60 μm.

14. The light emitting and receiving module with a heater according to claim 1, wherein the electrode includes a thickness of 100 nm to 15 μm.

15. The snow melting method according to claim 4, wherein
when the floating capacitance between the light emitting and receiving element and the heater film increases from an initial value by 20% to 50%, the detecting detects that the snow adhesion is present.

16. The snow melting method according to claim 4, further comprising heating a protective layer formed on a surface of the heater film with the electrode to melt snow.

17. A device having a light emitting and receiving module with a heater, the device comprising:
a base material;
a light emitting and receiving element that is disposed on the base material and configured to emit or receive light;
a heater film having an electrode formed on a base sheet, the heater film being formed so as to cover the light emitting and receiving element;
a capacitance detection unit electrically connected to the electrode to detect a floating capacitance between the light emitting and receiving element and the heater film;
a power source electrically connected to the electrode to heat the heater film; and
a control board that switches the connection with the electrode between the capacitance detection unit and the power source.

18. The device of claim 17, further comprising a lens between the light emitting and receiving element and the heater film.

19. The device of claim 17, wherein the light emitting and receiving element includes a plurality of light-emitting diodes (LEDs).

20. The device of claim 19, further comprising an LED lighting control board electrically connected to the plurality of LEDs.
